(19) United States
(12) Patent Application Publication
(10) Pub. No.: US 2007/0057695 A1
(43) Pub. Date: Mar. 15, 2007

(54) Semiconductor memory chip with re-drive unit for electrical signals

(76) Inventors: Hermann Ruckerbauer, Moos (DE); Peter Gregorius, Muenchen (DE)

Correspondence Address: EDELL, SHAPIRO & FINNAN, LLC, 1901 RESEARCH BLVD., SUITE 400, ROCKVILLE, MD, 20850, US

(21) Appl. No.: 11/226,456

(22) Filed: Sep. 15, 2005

(51) Int. Cl. H03K 19/0175

(52) U.S. Cl. 326/82

(57) ABSTRACT

A semiconductor memory chip includes a re-drive unit for re-driving electrical signals to at least one semiconductor memory chip connected thereto. The re-drive unit includes a direct line connection between two connecting nodes, i.e., one input terminal and one output terminal of the semiconductor memory chip.

### FIELD OF THE INVENTION

The present invention relates to semiconductor memories and, more particularly, to a semiconductor memory chip for a semiconductor memory array with a control and address bus serially connecting the semiconductor memory chips.

### BACKGROUND

In a conventional memory chip topology, for example, in DDR3 DRAMS, the individual memory chips are connected with each other by a flyby topology. Here, the individual memory chips are each connected in series to a flyby control and address bus. A major drawback of the flyby topology is a too narrow bandwidth and a too low structural density at high data rates of 1.6 Gbit/s/pin for example. Moreover, in the flyby topology, impedance discontinuities can occur at the connecting points (“balls”) of the memory chips on the flyby bus in an undesirable manner caused by the lines connected with the balls, the vias in the package, the bond wire and the input capacity of the attached chip and adversely affect the signal integrity.

To avoid these disadvantages, a semiconductor memory arrangement with an alternative memory chip topology including a unidirectional re-drive of control and address signals, read data, and write data that takes place between the semiconductor memory chips is desirable.

### SUMMARY

A semiconductor memory chip includes a re-drive unit for re-driving electrical signals, such as control and address signals, write data, and/or read data. Furthermore, an evaluation unit can cooperate with the re-drive unit to evaluate the electrical signals received. The evaluation unit cooperates with the re-drive unit such that re-drive unit re-drives electrical signals, for example, control and address signals, if, for instance, an evaluation of the electrical signals shows that this semiconductor memory chip is not an addressee of the electrical signals. However, re-driving electrical signals, for example, control and address signals, can take place, if an evaluation of the electrical signals received shows that the semiconductor memory chip is the addressee. The re-drive unit for re-driving electrical signals of the semiconductor memory chip according to the present invention includes a direct line connection between two connecting nodes, i.e., an input terminal and an output terminal of the semiconductor memory chip so that an electrical signal, such as control and address signals, write data, and/or read data, can be looped through the semiconductor memory chip. The re-drive unit of the semiconductor memory chip furthermore includes a series connection with a receiver and a transmitter. The series connection can be switched in parallel to the direct line connection between the two connecting nodes of the semiconductor memory chip. Signal conditioning can be achieved through the series connection of a receiver and a transmitter. Furthermore, circuits can be arranged between the receiver and the transmitter for resynchronization to a clock.

For example, the re-drive unit can have a branching line connection, wherein one branch of this line connection presents a direct connection to another semiconductor memory chip while the other branch of the line connection supplies the electrical signals to the semiconductor memory chip for processing/analysis. The control and address signals can first be evaluated by an evaluation unit in terms of their relevance.

In the semiconductor memory chip according to the invention, a switch (a transistor, for example) can be provided in the direct line connection between the two connecting nodes. Moreover, a switch (a transistor, for example) can be provided in the series connection having a receiver and a transmitter and being switched in parallel for the direct line connection between two connecting nodes. Optionally, the direct line connection between the connecting nodes and/or the series connection having a receiver and a transmitter can be conductively switched in this manner.

Furthermore, a terminating resistor can be provided in the re-drive unit to prevent undesirable signal reflections.

The semiconductor memory chip is, for example, a DRAM component (chip), which can be provided, for example, with a DDR interface.

The invention extends furthermore to a semiconductor memory array for operation in a data storage system with at least one semiconductor memory chip as described above for the storage of user data.

Such a semiconductor memory array includes, for example, a memory controller for control of the at least one semiconductor memory chip and the at least one unidirectional serial signal line bus connected with the memory controller for control and address signals that directly connects at least one semiconductor memory chip with the memory controller and serially connects the semiconductor memory chips among each other by 1-point-to-1-point connections.

Alternatively, such a semiconductor memory array can include a memory controller for the control of the at least one semiconductor memory chip and at least one unidirectional signal line bus connected with the memory controller for control and address signals, which directly connects at least one semiconductor memory chip with the memory controller, for instance, yet not necessary, by a branching connection, and the semiconductor memory chips among each other by a connection branching at least once. The signal line bus for control and address signals connecting the semiconductor memory chips is built, for example, from 1-point-to-m-point connections, with m being a natural number in a range from 1 to 4 so that the branching signal line bus will connect, in signal line direction, one semiconductor memory chip each with 1 additional semiconductor memory chip or 2 or 3 or 4 additional semiconductor memory chips to thus build up a tree-like branching structure. Viewed against the signal line direction, i.e., on the signal receiving side, every semiconductor memory chip is connected with only one single signal line each so that each semiconductor memory chip each is connected with one single signal line supplying the control and address signals and a plurality, for example, 1 to 3, of signal lines of the signal line bus re-driving the control and address signals.

Such semiconductor memory arrays can furthermore be provided with at least one serial signal line bus for read data, which has, between the semiconductor memory chips, the same signal line direction as the unidirectional signal line bus for control and address signals. The signal line bus for read data serially connects the semiconductor memory chips among each other by 1-point-to-1-point connections and directly connects at least one semiconductor memory chip with the memory controller. Furthermore, such semiconductor memory arrays can be provided with at least one serial signal line bus for write data, which has, between the semiconductor memory chips, the same signal line direction as the unidirectional signal line bus for control and address signals. The signal line bus for write data serially connects the semiconductor memory chips among each other by 1-point-to-1-point connections and directly connects at least one semiconductor memory chip with the memory controller.

Furthermore, the invention extends to a data storage system with a semiconductor memory array as described above.

### BRIEF DESCRIPTION OF THE FIGURE

The invention will now be explained in detail with reference to the enclosed drawing.

FIG. 1 schematically illustrates a serial interconnection of semiconductor memory chips in accordance with the invention.

### DETAILED DESCRIPTION

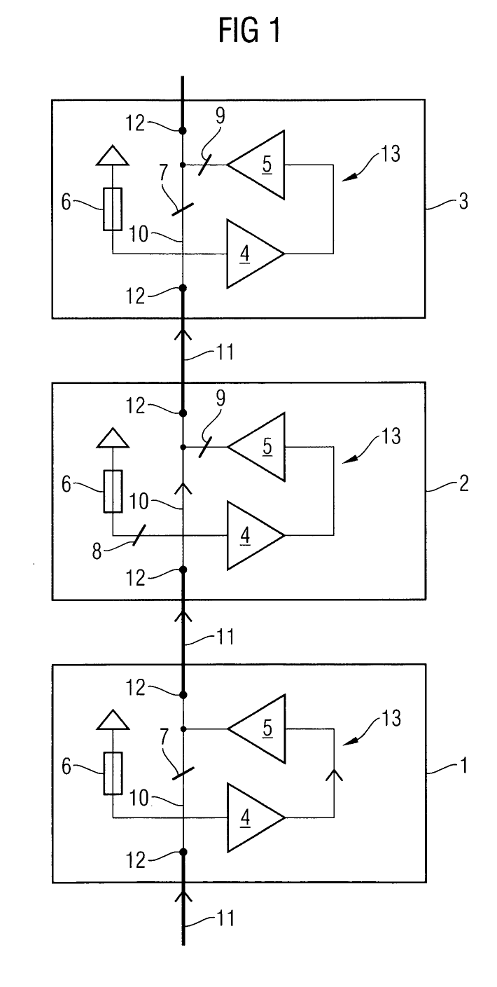

Referring to FIG. 1, three semiconductor memory chips 1, 2, 3 belonging to a “lane” are serially interconnected with each other by a signal wiring run of a signal line bus for control and address signals. The arrangement of the semiconductor memory chips 1, 2, 3 should be in accordance with the last three semiconductor memory chips within the lane, in accordance with the direction of the signal propagation indicated by the arrow tips, running from bottom to top in FIG. 1.

Each semiconductor memory chip 1, 2, 3 is provided with a re-drive unit 13 arranged between the corresponding connecting nodes 12. The unit 13 includes a direct electrical connecting line 10 between the pertinent connecting nodes 12, one series connection of receiver 4 and transmitter 5 switched in parallel to the direct electrical connecting line 10, and a terminating resistor 6. For example, in the semiconductor memory chip with the reference number 1, a switch 7 in closed position, e.g., a transistor, is provided in the electrical connection line 10, directly connecting the two connecting nodes 12, the switch taking care that the electrical signal, for example, the address and control signal, supplied to the semiconductor memory chip 1 is passed through the series connection of receiver 4 and transmitter 5, whereby a signal conditioning can be achieved. At the same time, the terminating resistor 6 prevents undesirable signal reflections. Although not shown in FIG. 1, the control and address signals supplied to the semiconductor memory chip 1 are relatively simultaneously passed to a logic (not shown) of the semiconductor memory chip 1 for processing/analysis/evaluation, wherein the signal conditioned by the series connection of receiver 4 and transmitter 5 is preferably supplied.

Subsequently, the electrical signals conditioned by the semiconductor memory chip 1, such as control and address signals, are supplied to the semiconductor memory chip with the reference number 2 by the signal line 11 of the signal line bus. The semiconductor memory chip 2 is provided with a switch 8 in closed position (e.g., a transistor) for the terminating resistor 6 and a switch 9 (e.g., transistor) in closed position, in the signal line direction behind the transmitter 9 so that the electrical signal, such as a control and address signal, supplied to the semiconductor memory chip 2 is supplied by the direct electrical connection line 10 to the connected semiconductor memory chip with the reference number 3. Although not shown in FIG. 1, the electrical signals, such as control and address signals, supplied to the semiconductor memory chip 2 are relatively simultaneously supplied to a logic (not shown) of the semiconductor memory chip 2 for processing/analysis/evaluation, wherein the signal conditioned by the series connection of receiver 4 and transmitter 5 is preferably supplied.

Finally, the electrical signals, for example, the control and address signals, are supplied to the semiconductor memory chip with the reference number 3, by the signal line 11 of the signal line bus, for example, for control and address signals. The semiconductor memory chip 3 is provided with a switch 7 being in closed position (e.g., a transistor) for the direct electrical connection line 10 and with a switch 9 in closed position (e.g., a transistor) in the direction of the signal line behind the transmitter 9 so that no re-drive of the supplied electrical signal, such as a control and address signal, takes place. Moreover, the terminating resistor 6 prevents an undesirable signal reflection. Although not shown in FIG. 1, the electrical signals, such as control and address signals, supplied to the semiconductor memory chip 3, are simultaneously supplied to a logic (not shown) of the semiconductor memory chip 3 for processing/analysis/evaluation, wherein the signal conditioned by the series connection of receiver 4 and transmitter 5 is preferably supplied.

While the invention has been described in detail and with reference to specific embodiments thereof, it will be apparent to one skilled in the art that various changes and modifications can be made therein without departing from the spirit and scope thereof. For example, some or all of the subject matter may be embodied as software, hardware or a combination thereof. Accordingly, it is intended that the present invention covers the modifications and variations of this invention provided they come within the scope of the appended claims and their equivalents.

### LIST OF REFERENCE NUMBERS

1 Semiconductor memory chip
2 Semiconductor memory chip
3 Semiconductor memory chip
4 Receiver
5 Transmitter
6 Terminating resistor
7 Switch
8 Switch
9 Switch
10 Direct line connection
11 Signal wiring run, control and address signal bus
12 Connecting node
13 Re-drive unit

What is claimed:

1. A semiconductor memory chip, comprising:
a re-drive unit for re-driving electrical signals to at least one semiconductor memory chip connected thereto, the re-drive unit having a direct line connection between two connecting nodes, the direct connection being one input terminal and one output terminal of the semiconductor memory chip.

2. The semiconductor memory chip according to claim 1, wherein the re-drive unit includes a series connection having a receiver and a transmitter, the series connection being switched in parallel for the direct line connection between the two connecting nodes of the semiconductor memory chip.

3. The semiconductor memory chip according to claim 1, wherein one switch is provided in the direct line connection between the two connecting nodes.

4. The semiconductor memory chip according to claim 1, wherein one switch is provided in the series connection having one receiver and one transmitter, the one switch being switched in parallel for the direct line connection between two connecting nodes.

5. The semiconductor memory chip according to claim 1, wherein the re-drive unit includes a terminating resistor.

6. The semiconductor memory chip according to claim 1, wherein the semiconductor memory chip is a DRAM chip.

7. The semiconductor memory chip according to claim 6, wherein the DRAM chip has a DDR interface.

8. A semiconductor memory array for the operation in a data storage system with at least one semiconductor memory chip for the storage of user data, comprising:
a semiconductor memory chip including
a re-drive unit for re-driving electrical signals to at least one semiconductor memory chip connected thereto, the re-drive unit having a direct line connection between two connecting nodes, the direct connection being one input terminal and one output terminal of the semiconductor memory chip.

9. The semiconductor memory array for the operation in a data storage system with at least one semiconductor memory chip for the storage of user data according to claim 8, further comprising:
a memory controller for control of the at least one semiconductor memory chip; and
at least one unidirectional, serial signal line bus for control and address signals, connected with the memory controller and directly connecting at least one semiconductor memory chip with the memory controller, and serially connecting the semiconductor memory chips among each other by 1-point-to-1-point connections.

10. The semiconductor memory array for the operation in a data storage system with at least one semiconductor memory chip for the storage of useful data according to claim 8, further comprising:
a memory controller for control of the at least one semiconductor memory chip; and
at least one unidirectional signal line bus for control and address signals, connected with the memory controller and directly connecting at least one semiconductor memory chip with the memory controller, and connecting the semiconductor memory chips among each other by a connection branching at least once.

11. The semiconductor memory array according to claim 9, further comprising:
at least one serial signal line bus for read data, having the same signal line direction as the unidirectional signal line bus for control and address signals between the semiconductor memory chips, wherein the unidirectional signal line bus for read data serially connects the semiconductor memory chips among each other by 1-point-to-1-point connections, and directly connects at least one semiconductor memory chip with the memory controller.

12. The semiconductor memory array according to claim 9, further comprising:
at least one serial signal line bus for write data, having the same signal line direction as the unidirectional signal line bus for control and address signals between the semiconductor memory chips, wherein the unidirectional signal line bus for write data serially connects the semiconductor memory chips among each other by 1-point-to-1-point connections, and directly connects at least one semiconductor memory chip with the memory controller.

13. The semiconductor memory array according to claim 10, further comprising:
at least one serial signal line bus for read data, having the same signal line direction as the unidirectional signal line bus for control and address signals between the semiconductor memory chips, wherein the unidirectional signal line bus for read data serially connects the semiconductor memory chips among each other by 1-point-to-1-point connections, and directly connects at least one semiconductor memory chip with the memory controller.

14. The semiconductor memory array according to claim 10, further comprising:
at least one serial signal line bus for write data, having the same signal line direction as the unidirectional signal line bus for control and address signals between the semiconductor memory chips, wherein the unidirectional signal line bus for write data serially connects the semiconductor memory chips among each other by 1-point-to-1-point connections, and directly connects at least one semiconductor memory chip with the memory controller.

15. A data storage system with a semiconductor memory array for operation in a data storage system with at least one semiconductor memory chip for the storage of user data, comprising:
a semiconductor memory chip including
a re-drive unit for re-driving electrical signals to at least one semiconductor memory chip connected thereto, the re-drive unit having a direct line connection between two connecting nodes, the direct connection being one input terminal and one output terminal of the semiconductor memory chip.
